(19) United States
(12) Patent Application Publication
(10) Pub. No.: US 2022/0309972 A1
(43) Pub. Date: Sep. 29, 2022

(54) Driving Circuit and Driving Method Thereof, and Display Panel

(71) Applicants: Chengdu BOE Optoelectronics Technology Co., Ltd., Chengdu, Sichuan (CN); BOE Technology Group Co., Ltd., Beijing (CN)

(72) Inventors: Shuzhen YANG, Beijing (CN); Zhiyong YANG, Beijing (CN); Liwei HUANG, Beijing (CN); Kaimin WANG, Beijing (CN); Wei LIU, Beijing (CN); Xiaohong CHEN, Beijing (CN)

(21) Appl. No.: 17/431,183

(22) PCT Filed: Feb. 19, 2021
(86) PCT No.: PCT/CN2021/076888

§ 371 Date: Aug. 16, 2021

(30) Foreign Application Priority Data
Apr. 26, 2020 (CN) 202010339941.3

(51) Int. Cl. G09G 3/00

(52) U.S. Cl. CPC G09G 3/035; G09G 2310/0286; G09G 2310/08; G09G 2330/028

(57) ABSTRACT

A driving circuit, a driving method thereof, and a display panel are provided. The driving circuit includes: a first shift register group, including multiple stages of shift register circuits, first gate input terminals of the second stage to the last stage being connected with gate output terminals of the immediately previous stages; a second shift register group, including multiple stages of shift register circuits, second gate input terminals of the second stage to the last stage being connected with gate output terminals of the immediately previous stages; and a control module, including a first GSTV signal output terminal and a second GSTV signal output terminal. The control module is arranged to output a first turn-on signal or a first turn-off signal to the first GSTV signal output terminal and the second GSTV signal output terminal respectively.

### CROSS-REFERENCE TO RELATED APPLICATIONS

The present application is a U.S. National Phase Entry of International Application No. PCT/CN2021/076888 having an international filing date of Feb. 19, 2021, which claims priority to Chinese patent application No. 202010339941.3, filed to CNIPA on Apr. 26, 2020, and entitled “A Driving Circuit and Driving Method Thereof, and Display Panel”. The entire contents of the above-identified applications are hereby incorporated by reference.

### TECHNICAL FIELD

Embodiments of the present disclosure relate, but not limited, to the technical field of display driving, and particularly to a driving circuit and a driving method thereof, and a display panel.

### BACKGROUND

In recent years, flexible Organic Light-Emitting Diode (OLED) display panel has been developed rapidly from curved display screen to foldable display screen, from bending within 90° to 180° folding, and from 5.5 inches gradually to 8 inches. An enlarged display screen inevitably requires a higher driving capability of an Integrated Circuit (IC), or is driven by multiple ICs. The improvement of the driving capability of the IC may increase the power consumption and result in the poor endurance of the display panel. It is needed to reduce the power consumption of a display panel to improve the endurance of the display panel.

### SUMMARY

The below is a summary about the subject matter described in the present disclosure in detail. The summary is not intended to limit the scope of protection of the claims.

According to a first aspect, an embodiment of the present disclosure provides a driving circuit, which includes: a first shift register group, including multiple stages of shift register circuits, where the shift register circuit of each stage includes a first gate input terminal and a gate output terminal, and the first gate input terminals of the shift register circuits of the second stage to the last stage are connected with the gate output terminals of the shift register circuits of the immediately previous stages; a second shift register group, including multiple stages of shift register circuits, where the shift register circuit of each stage includes a second gate input terminal and a gate output terminal, and the second gate input terminals of the shift register circuits of the second stage to the last stage are connected with the gate output terminals of the shift register circuits of the immediately previous stages; and a control module, including a first Gate Start Voltage (GSTV) signal output terminal and a second GSTV signal output terminal. The first GSTV signal output terminal is connected with the first gate input terminal of the shift register circuit of the first stage in the first shift register group. The second GSTV signal output terminal is connected with the second gate input terminal of the shift register circuit of the first stage in the second shift register group. The control module is arranged to output a first turn-on signal or a first turn-off signal to the first GSTV signal output terminal, and is further arranged to output the first turn-on signal or the first turn-off signal to the second GSTV signal output terminal.

In an exemplary embodiment, the first turn-off signal includes a high-impedance state.

In an exemplary embodiment, in the first shift register group, the shift register circuit of each stage further includes a first enable input terminal and an enable output terminal, and the first enable input terminals of the shift register circuits of the second stage to the last stage are connected with the enable output terminals of the shift register circuits of the immediately previous stages.

In the second shift register group, the shift register circuit of each stage further includes a second enable input terminal and an enable output terminal, and the second enable input terminals of the shift register circuits of the second stage to the last stage are connected with the enable output terminals of the shift register circuits of the immediately previous stages.

The control module further includes a first Emission Start Voltage (ESTV) signal output terminal and a second ESTV signal output terminal. The first ESTV signal output terminal is connected with the first enable input terminal of the shift register circuit of the first stage in the first shift register group. The second ESTV signal output terminal is connected with the second enable input terminal of the shift register circuit of the first stage in the second shift register group. The control module is arranged to output a second turn-on signal or a second turn-off signal to the first ESTV signal output terminal, and is further arranged to output the second turn-on signal or the second turn-off signal to the second ESTV signal output terminal.

In an exemplary embodiment, the second turn-off signal includes the high-impedance state.

In an exemplary embodiment, the shift register circuit further includes a first signal terminal, a second signal terminal, a third signal terminal, and a fourth signal terminal. The first signal terminal is connected with a first clock signal line. The second signal terminal is connected with a second clock signal line. The third signal terminal is connected with a third clock signal line. The fourth signal terminal is connected with a fourth clock signal line. The first clock signal and the second clock signal have the same period and opposite states. The third clock signal and the fourth clock signal have the same period and opposite states.

In an exemplary embodiment, the driving circuit further includes a first detection unit and second detection unit that are connected with the control module. The control module is arranged to output the first turn-on signal or the first turn-off signal to the first GSTV signal output terminal according to a detection signal of the first detection unit and output the first turn-on signal or the first turn-off signal to the second GSTV signal output terminal according to a detection signal of the second detection unit.

In an exemplary embodiment, the driving circuit further includes a first detection unit and second detection unit that are connected with the control module. The control module is arranged to output the second turn-on signal or the second turn-off signal to the first ESTV signal output terminal according to a detection signal of the first detection unit and output the second turn-on signal or the second turn-off signal to the second ESTV signal output terminal according to a detection signal of the second detection unit.

In an exemplary embodiment, the driving circuit further includes: a third shift register group, including multiple stages of shift register circuits. The shift register circuit of each stage includes a third gate input terminal, a gate output terminal, a third enable input terminal, and an enable output terminal. The third gate input terminals of the shift register circuits of the second stage to the last stage are connected with the gate output terminals of the shift register circuits of the immediately previous stages. The third enable input terminals of the shift register circuits of the second stage to the last stage are connected with the enable output terminals of the shift register circuits of the immediately previous stages.

The control module further includes a third GSTV signal output terminal and a third ESTV signal output terminal. The third GSTV signal output terminal is connected with the third gate input terminal of the shift register circuit of the first stage in the third shift register group. The third ESTV signal output terminal is connected with the third enable input terminal of the shift register circuit of the first stage in the third shift register group. The control module is arranged to output the first turn-on signal or the first turn-off signal to the third GSTV signal output terminal to turn on or off the gate output terminal of the third shift register group, and is further arranged to output the second turn-on signal or the second turn-off signal to the third ESTV signal output terminal to turn on or off the enable output terminal of the third shift register group.

According to a second aspect, an embodiment of the present disclosure also provides a display panel, which is a foldable display panel and includes a display region and a border region at a periphery of the display region. The display region is folded to form a first display sub-region and a second display sub-region. The display panel includes the abovementioned driving circuit. Each of the first display sub-region and the second display sub-region includes multiple gate lines. The gate output terminals of the multiple stages of shift register circuits in the first shift register group are connected with the multiple gate lines of the first display sub-region in one-to-one correspondence. The gate output terminals of the multiple stages of shift register circuits in the second shift register group are connected with the multiple gate lines of the second display sub-region in one-to-one correspondence.

In an exemplary embodiment, the display panel is folded to further form a third display sub-region. The third display sub-region includes multiple gate lines. The driving circuit further includes a third shift register group. Gate output terminals of multiple stages of shift register circuits in the third shift register group are connected with the multiple gate lines of the third display sub-region in one-to-one correspondence.

In an exemplary embodiment, the driving circuit further includes a first detection unit and a second detection unit. The first detection unit is arranged to detect a folding state of the first display sub-region. The second detection unit is arranged to detect a folding state of the second display sub-region.

According to a third aspect, an embodiment of the present disclosure also provides a driving method of a driving circuit, applied to the abovementioned driving circuit and including the following operations.

A detection signal of a first detection unit is received, and a first turn-off signal is output to a first GSTV signal output terminal when the detection signal of the first detection unit is a folding signal.

A detection signal of a second detection unit is received, and a first turn-on signal is output to a second GSTV signal output terminal when the detection signal of the second detection unit is an unfolding signal.

In an exemplary embodiment, the driving method further includes the following operations.

A second turn-off signal is output to a first ESTV signal output terminal when the detection signal of the first detection unit is a folding signal.

A second turn-on signal is output to a second ESTV signal output terminal when the detection signal of the second detection unit is an unfolding signal.

After the drawings and the detailed descriptions are read and understood, the other aspects may be comprehended.

### BRIEF DESCRIPTION OF DRAWINGS

The drawings provide an understanding of the technical solutions of the present disclosure, form a part of the specification, and are used to explain, together with the embodiments of the present disclosure, the technical solutions of the present disclosure and not intended to form limits to the technical solutions of the present disclosure.

FIG. 1 illustrates a driving circuit of a foldable display panel.

FIG. 2 is a schematic diagram of a driving circuit according to an exemplary embodiment of the present disclosure.

FIG. 3 is a schematic diagram of a foldable display panel.

FIG. 4 is a schematic diagram of a shift register circuit.

FIG. 5 is a structural schematic diagram of a gate driving unit applicable to the shift register circuit in FIG. 2.

FIG. 6 is a working sequence diagram of the gate driving unit in FIG. 5.

FIG. 7 is a structural schematic diagram of an enable driving unit applicable to the shift register circuit in FIG. 2.

FIG. 8 is a working sequence diagram of the enable driving unit in FIG. 7.

FIGS. 9a to 9c are schematic signal state diagrams of a gate output terminal and enable output terminal of a display panel when a first display sub-region is in a folded state.

FIGS. 10a to 10c are schematic signal state diagrams of a gate output terminal and enable output terminal of a display panel when both a first display sub-region and a second display sub-region are in a folded state.

FIGS. 11a to 11c are schematic signal state diagrams of a gate output terminal and enable output terminal of a display panel when a first display sub-region and a third display sub-region are in a folded state.

FIG. 12 is a schematic diagram of a driving circuit according to an exemplary embodiment.

FIG. 13 is a schematic diagram of a driving method according to an exemplary embodiment of the present disclosure.

### DETAILED DESCRIPTION

Multiple embodiments are described in the present disclosure. However, the description is exemplary and unrestrictive. Moreover, those of ordinary skill in the art may obtain more embodiments and implementation solutions in the scope of the embodiments described in the present disclosure. Although many possible feature combinations are shown in the drawings and discussed in specific implementation modes, the disclosed features may also be combined in many other manners. Unless specifically restricted, any feature or element of any embodiment may be combined with any other feature or element in any other embodiment for use, or may take the place of any other feature or element in any other embodiment.

The present disclosure includes and conceives combinations of features and elements well known to those of ordinary skill in the art. The embodiments, features, and elements that have been disclosed in the present disclosure may be combined with any conventional features or elements to form unique solutions defined by the claims. Any feature or element of any embodiment may be combined with a feature or element from another solution to form another unique solution defined by the claims. Therefore, any feature shown and/or discussed in the present disclosure may be implemented independently or in any appropriate combination. Therefore, no other limits are made to the embodiments, besides limits made by the appended claims and equivalent replacements thereof. In addition, various modifications and variations may be made within the scope of protection of the appended claims.

In addition, a method and/or a process may already be presented as a specific step sequence in the specification when a representative embodiment is described. However, the method or the process should not be limited to the steps of the specific sequence on the premise that the method or the process is independent of the specific sequence of the steps. As understood by those of ordinary skill in the art, other step sequences are possible. Therefore, the specific sequence of the steps described in the specification should not be explained as a limit to the claims. Moreover, execution of the steps of the method and/or the process in the claims for the method and/or the process should not be limited to the written sequence, and it can be understood by those skilled in the art that these sequences may be changed and still fall within the spirit and scope of the embodiments of the present disclosure.

Unless otherwise defined, technical terms or scientific terms used in the embodiments of the present disclosure should have the same meanings as commonly understood by those of ordinary skill in the art that the present disclosure belongs to. Ordinal numerals “first”, “second”, “third”, etc., used in the embodiments of the present disclosure do not represent any sequence, number, or importance, and are set not to form limits in number but only to avoid the confusion of composition elements. “Include”, “contain”, or a similar term means that an element or object appearing before the term covers an element or object and equivalent thereof listed after the term and does not exclude other elements or objects. “Connect”, “mutually connected”, or similar terms are not limited to physical or mechanical connection but may include electrical connection, either direct or indirect.

It can be understood by those skilled in the art that transistor adopted in all the embodiments of the present disclosure may be a thin-film transistor, or a field-effect transistor, or another device with the same characteristic. The thin-film transistor used in the embodiments of the present disclosure may be an oxide semiconductor transistor. A source and drain of the transistor used here are symmetric, so the drain and the source may be interchanged. In the embodiments of the present disclosure, the gate of the transistor is called a control electrode. For distinguishing the two electrodes, except the gate, of the transistor, one electrode is called a first electrode, while the other electrode is called a second electrode. The first electrode may be the source or the drain, and the second electrode may be the drain or the source.

Two main aspects are considered for reduction of the power consumption of an IC: one is a power supply manner for the IC, and the other is a driving manner for a display panel. Some IC products may be powered by two to four lines, and the power consumption is different when different power supply manners are adopted to turn on the picture. The driving manner for the display panel may be matched with the IC to reduce the power consumption, and particularly for a foldable screen, the power consumption is improved more remarkably.

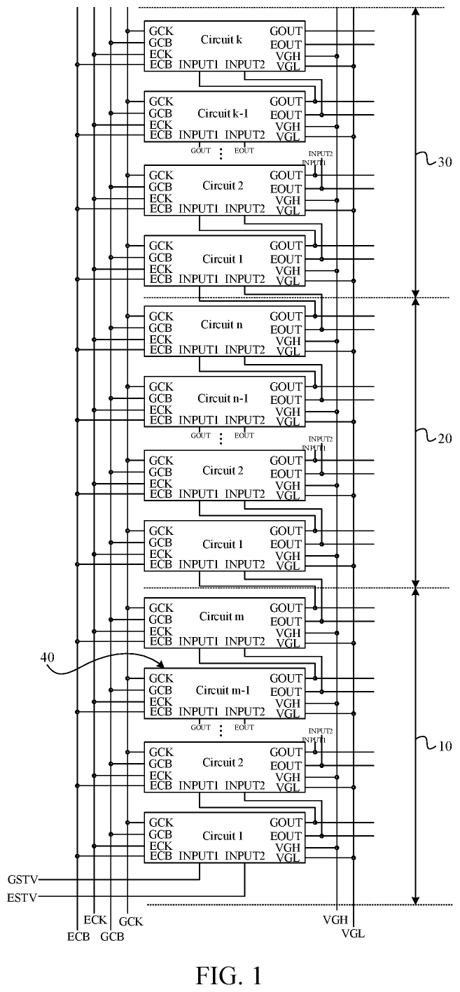

FIG. 1 illustrates a driving circuit of a foldable display panel. As shown in FIG. 1, the display panel is folded to form three display sub-regions, i.e., a first display sub-region 10, a second display sub-region 20, and a third display sub-region 30 respectively. The driving circuit includes three shift register groups. The three shift register groups include a first shift register group in the first display sub-region 10, a second shift register group in the second display sub-region 20, and a third shift register group in the third display sub-region 30. The first shift register group includes m stages of sequentially cascaded shift register circuits 40. The second shift register group includes n stages of sequentially cascaded shift register circuits 40. The third shift register group includes k stages of sequentially cascaded shift register circuits 40. The shift register circuit 40 includes a first input terminal INPUT1, a second input terminal INPUT2, a gate output terminal GOUT, an enable output terminal EOUT, a first signal terminal GCK, a second signal terminal GCB, a third signal terminal ECK, a fourth signal terminal ECB, a first power terminal VGH, and a second power terminal VGL. The first signal terminal GCK, second signal terminal GCB, third signal terminal ECK, and fourth signal terminal ECB of the shift register circuit 40 are respectively sequentially connected with a first clock signal line GCK, a second clock signal line GCB, a third clock signal line ECK, and a fourth clock signal line ECB. The first power terminal VGH and second power terminal VGL of the shift register circuit 40 are respectively sequentially connected with a first power line VGH and a second power line VGL.

As shown in FIG. 1, in each display sub-region, the first input terminals INPUT1 of the shift register circuits 40 of the second stage to the last stage are connected with the gate output terminals GOUT of the shift register circuits of the immediately previous stages, and the second input terminals INPUT2 of the shift register circuits 40 of the second stage to the last stage are connected with the enable output terminals EOUT of the shift register circuits of the immediately previous stages. The first input terminal INPUT1 of the shift register circuit of the first stage in the first display sub-region 10 is connected with a Gate Start Voltage (GSTV) signal line, while the second input terminal INPUT2 is connected with an Emission Start Voltage (ESTV) signal line. The first input terminal INPUT1 of the shift register circuit of the first stage in the second display sub-region 20 is connected with the gate output terminal GOUT of the shift register circuit of the last stage in the first display sub-region 10, while the second input terminal INPUT2 of the shift register circuit of the first stage is connected with the enable output terminal EOUT of the shift register circuit of the last stage in the first display sub-region 10. The first input terminal INPUT1 of the shift register circuit of the first stage in the third display sub-region 30 is connected with the gate output terminal GOUT of the shift register circuit of the last stage in the second display sub-region 20, while the second input terminal INPUT2 of the shift register circuit of the first stage is connected with the enable output terminal EOUT of the shift register circuit of the last stage in the second display sub-region 20.

A single GSTV/ESTV signal is adopted in multiple display sub-regions to drive the whole screen in the driving circuit shown in FIG. 1. After the panel is folded, a black picture is displayed by black screen refreshing in a display sub-region required to be turned off. A display region may be selected by black screen refreshing. However, black screen refreshing is not performed on a display sub-region that is not displayed, a shift register circuit of the display sub-region that is not displayed is required to keep working, and a gate output terminal is required to keep outputting a gate driving signal. Consequently, IC power is wasted.

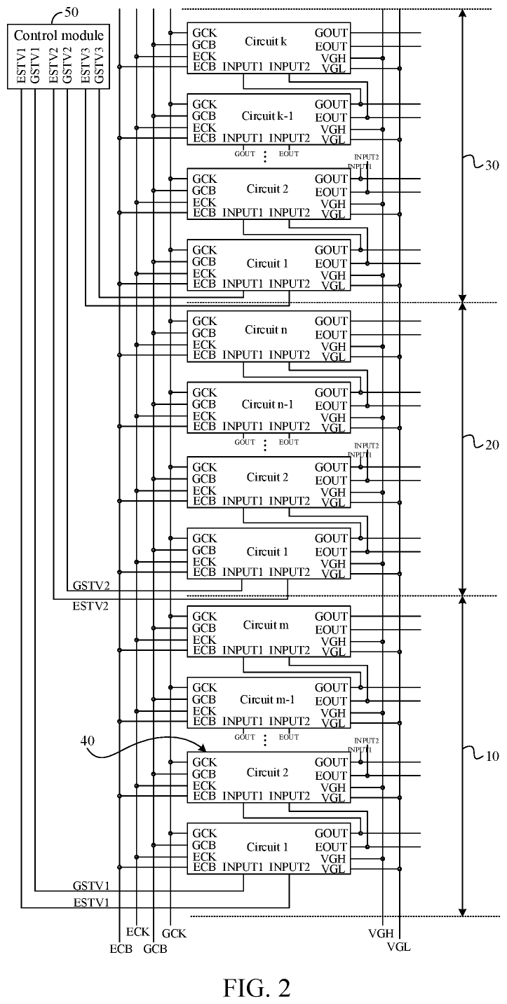

FIG. 2 is a schematic diagram of a driving circuit according to an exemplary embodiment of the present disclosure. As shown in FIG. 2, the present disclosure provides a driving circuit, which may be applied to a foldable display panel.

The driving circuit includes a first shift register group, a second shift register group, and a control module 50. The first shift register group includes multiple stages of shift register circuits 40. The shift register circuit 40 of each stage includes a first gate input terminal INPUT1 and a gate output terminal GOUT. The first gate input terminals INPUT1 of the shift register circuits of the second stage to the last stage are connected with the gate output terminals GOUT of the shift register circuits of the immediately previous stages.

The second shift register group includes multiple stages of shift register circuits 40. The shift register circuit of each stage includes a second gate input terminal INPUT1 and a gate output terminal GOUT. The second gate input terminals INPUT1 of the shift register circuits of the second stage to the last stage are connected with the gate output terminals GOUT of the shift register circuits of the immediately previous stages.

The control module includes a first GSTV signal output terminal GSTV1 and a second GSTV signal output terminal GSTV2. The first GSTV signal output terminal GSTV1 is connected with the first gate input terminal of the shift register circuit of the first stage in the first shift register group. The second GSTV signal output terminal GSTV2 is connected with the second gate input terminal of the shift register circuit of the first stage in the second shift register group. The control module is arranged to output a first turn-on signal or a first turn-off signal to the first GSTV signal output terminal GSTV1 to turn on or off the gate output terminal GOUT of the shift register circuit in the first shift register group, and is further arranged to output the first turn-on signal or the first turn-off signal to the second GSTV signal output terminal GSTV2 to turn on or off the gate output terminal GOUT of the shift register circuit in the second shift register group.

The driving circuit of the embodiment of the present disclosure may be applied to a foldable display panel. The display panel may be folded to form a first display sub-region and a second display sub-region. The first shift register group is arranged to drive the first display sub-region. The second shift register group is arranged to drive the second display sub-region.

It can be understood by those skilled in the art that, in a gate driving circuit, when a GSTV signal is an initial gate driving signal (i.e., a signal including a pulse in time of a frame of image), the gate driving circuit may be turned on and output a gate driving signal at a gate output terminal. In the embodiment of the present disclosure, the control module includes the first GSTV signal output terminal GSTV1 and the second GSTV signal output terminal GSTV2. The first GSTV signal output terminal GSTV1 is connected with the first gate input terminal of the shift register circuit of the first stage in the first shift register group. The second GSTV signal output terminal GSTV2 is connected with the second gate input terminal of the shift register circuit of the first stage in the second shift register group. The control module is arranged to output a first turn-on signal or a first turn-off signal to the first GSTV signal output terminal GSTV1 to turn on or off the gate output terminal GOUT of the shift register circuit in the first shift register group. The control module is further arranged to output the first turn-on signal or the first turn-off signal to the second GSTV signal output terminal GSTV2 to turn on or off the gate output terminal GOUT of the shift register circuit in the second shift register group. When the driving circuit is applied to the foldable display panel, each display sub-region corresponds to a single GSTV signal output terminal, and the control module may separately control the displaying of each display sub-region. When a display sub-region is in a folded state and not required to display anything, the control module may output the first turn-off signal to the GSTV signal output terminal corresponding to the display sub-region, thereby turning off a gate output terminal of a shift register circuit in a shift register corresponding to the display sub-region to stop the gate output terminal from outputting any gate driving signal and display a black picture in the display sub-region. The black picture is no more displayed by black screen refreshing in the display sub-region in the folded state, so that power wastes are avoided, the power consumption of the driving circuit is reduced, and the endurance of the display panel is improved.

In an exemplary embodiment, as shown in FIG. 2, the shift register circuit 40 may further include a first power terminal VGH, a second power terminal VGL, a first signal terminal GCK, and a second signal terminal GCB. The first power terminal VGH and second power terminal VGL of the shift register circuit 40 are respectively sequentially connected with a first power signal line VGH and a second power signal line VGL. That is, the first power terminal VGH of the shift register circuit 40 is connected with the first power signal line VGH, and the second power terminal of the shift register circuit 40 is connected with the second power signal line VGL. The first signal terminal GCK and second signal terminal GCB of the shift register circuit 40 are respectively sequentially connected with a first clock signal line GCK and a second clock signal line GCB. That is, the first signal terminal GCK of the shift register circuit 40 is connected with the first clock signal line GCK, and the second signal terminal GCB of the shift register circuit 40 is connected with the second clock signal line GCB. The first clock signal line GCK and the second clock signal line GCB have the same period and opposite states.

In an exemplary embodiment, the first turn-off signal may include a high-impedance state. The first turn-on signal may be an initial gate driving signal (i.e., a signal including a pulse in time of a frame of image). When the first display sub-region is in a folded state and the second display sub-region is in an unfolded state, the control module may input the first turn-off signal to the first GSTV signal output terminal GSTV1 to turn off the gate output terminal GOUT of the shift register circuit in the first shift register group to stop the gate output terminal GOUT from outputting any gate driving signal and stop displaying in the first display sub-region. The control module may input the first turn-on signal to the second GSTV signal output terminal GSTV2 to turn on the gate output terminal GOUT of the shift register circuit in the second shift register group to enable the gate output terminal GOUT to normally output a gate driving signal and implement displaying in the second display sub-region.

It can be understood by those skilled in the art that an output of a digital circuit has three states: a high level, a low level, and a high-impedance state. The high-impedance state is a common state in a digital circuit. The high-impedance state is neither a high level nor a low level. If the high-impedance state is further input to a next-stage circuit, the next-stage may not be affected, just as there is no connection. The high-impedance state may be a high level or a low level if measured by a voltmeter. The high-impedance state is the most power-saving output manner, and reduces the power consumption of the display panel.

In an exemplary embodiment, in the first shift register group, the shift register circuit of each stage further includes a first enable input terminal INPUT2 and an enable output terminal EOUT, and the first enable input terminals INPUT2 of the shift register circuits of the second stage to the last stage are connected with the enable output terminals EOUT of the shift register circuits of the immediately previous stages. In the second shift register group, the shift register circuit of each stage further includes a second enable input terminal INPUT2 and an enable output terminal EOUT, and the second enable input terminals INPUT2 of the shift register circuits of the second stage to the last stage are connected with the enable output terminals EOUT of the shift register circuits of the immediately previous stages. The control module further includes a first ESTV signal output terminal ESTV1. The first ESTV signal output terminal ESTV1 is connected with the first enable input terminal INPUT2 of the shift register circuit of the first stage in the first shift register group. The first enable input terminal INPUT2 of the shift register circuit of the first stage in the second shift register group is connected with the enable output terminal EOUT of the shift register circuit of the last stage in the first shift register group. The control module is arranged to output a second turn-on signal or a second turn-off signal to the first ESTV signal output terminal ESTV1.

In an exemplary embodiment, as shown in FIG. 2, in the first shift register group, the shift register circuit of each stage further includes a first enable input terminal INPUT2 and an enable output terminal EOUT, and the first enable input terminals INPUT2 of the shift register circuits of the second stage to the last stage are connected with the enable output terminals EOUT of the shift register circuits of the immediately previous stages. In the second shift register group, the shift register circuit of each stage further includes a second enable input terminal INPUT2 and an enable output terminal EOUT, and the second enable input terminals INPUT2 of the shift register circuits of the second stage to the last stage are connected with the enable output terminals EOUT of the shift register circuits of the immediately previous stages.

The control module further includes a first ESTV signal output terminal ESTV1 and a second ESTV signal output terminal ESTV2. The first ESTV signal output terminal ESTV1 is connected with the first enable input terminal INPUT2 of the shift register circuit of the first stage in the first shift register group. The second ESTV signal output terminal ESTV2 is connected with the second enable input terminal INPUT2 of the shift register circuit of the first stage in the second shift register group. The control module is arranged to output a second turn-on signal or a second turn-off signal to the first ESTV signal output terminal ESTV1 to turn on or off the enable output terminal EOUT of the shift register circuit in the first shift register group. The control module is arranged to output the second turn-on signal or the second turn-off signal to the second ESTV signal output terminal ESTV2 to turn on or off the enable output terminal EOUT of the shift register circuit in the second shift register group.

It can be understood by those skilled in the art that, in an enable driving circuit, when an ESTV signal is an initial enable driving signal (i.e., a signal including a pulse in time of a frame of image), the enable driving circuit may be turned on and output an enable driving signal at an enable output terminal. In the embodiment of the present disclosure, when the driving circuit is applied to the foldable display panel, each display sub-region corresponds to a single ESTV signal output terminal, and the control module may separately control the enable driving of each display sub-region. When a display sub-region is in a folded state and does not need enable driving, the control module may output the second turn-off signal to the ESTV signal output terminal corresponding to the display sub-region, thereby turning off an enable output terminal of a shift register circuit in a shift register corresponding to the display sub-region to stop the enable output terminal from outputting any enable driving signal. As such, the power consumption is reduced, and the endurance of the display panel is improved.

In an exemplary embodiment, as shown in FIG. 2, the shift register circuit 40 may further include a third signal terminal ECK and a fourth signal terminal ECB. The third signal terminal ECK and fourth signal terminal ECB of the shift register circuit 40 are respectively sequentially connected with a third clock signal line ECK and a fourth clock signal line ECB. That is, the third signal terminal ECK of the shift register circuit 40 is connected with the third clock signal line ECK, and the fourth signal terminal ECB of the shift register circuit 40 is connected with the fourth clock signal line ECB. The third clock signal line ECK and the fourth clock signal line ECB have the same period and opposite states.

In an exemplary embodiment, the second turn-off signal may include a high-impedance state. The second turn-on signal may be an initial enable driving signal (i.e., a signal including a pulse in time of a frame of image). When the first display sub-region is in a folded state and the second display sub-region is in an unfolded state, the control module may input the first turn-off signal to the first ESTV signal output terminal ESTV1 to turn off the enable output terminal EOUT of the shift register circuit in the first shift register group to stop the enable output terminal EOUT from outputting any enable driving signal. The control module may input the first turn-on signal to the second ESTV signal output terminal ESTV2 to turn on the enable output terminal EOUT of the shift register circuit in the second shift register group to enable the enable output terminal EOUT to normally output an enable driving signal.

In an exemplary embodiment, as shown in FIG. 2, the driving circuit further includes a third shift register group. The third shift register group includes multiple stages of shift register circuits. The shift register circuit of each stage includes a third gate input terminal INPUT1 and a gate output terminal GOUT. The third gate input terminals of the shift register circuits of the second stage to the last stage are connected with the gate output terminals of the shift register circuits of the immediately previous stages. The shift register circuit of each stage further includes a third enable input terminal INPUT2 and an enable output terminal EOUT. The third enable input terminals of the shift register circuits of the second stage to the last stage are connected with the enable output terminals of the shift register circuits of the immediately previous stages.

The control module further includes a third GSTV signal output terminal GSTV3. The third GSTV signal output terminal GSTV3 is connected with the third gate input terminal INPUT1 of the shift register circuit of the first stage in the third shift register group. The control module is arranged to output the first turn-on signal or the first turn-off signal to the third GSTV signal output terminal GSTV3 to turn on or off the gate output terminal GOUT of the third shift register group.

The control module further includes a third ESTV signal output terminal ESTV3. The third ESTV signal output terminal ESTV1 is connected with the third enable input terminal INPUT2 of the shift register circuit of the first stage in the third shift register group. The control module is further arranged to output the second turn-on signal or the second turn-off signal to the third ESTV signal output terminal ESTV3 to turn on or off the enable output terminal EOUT of the third shift register group.

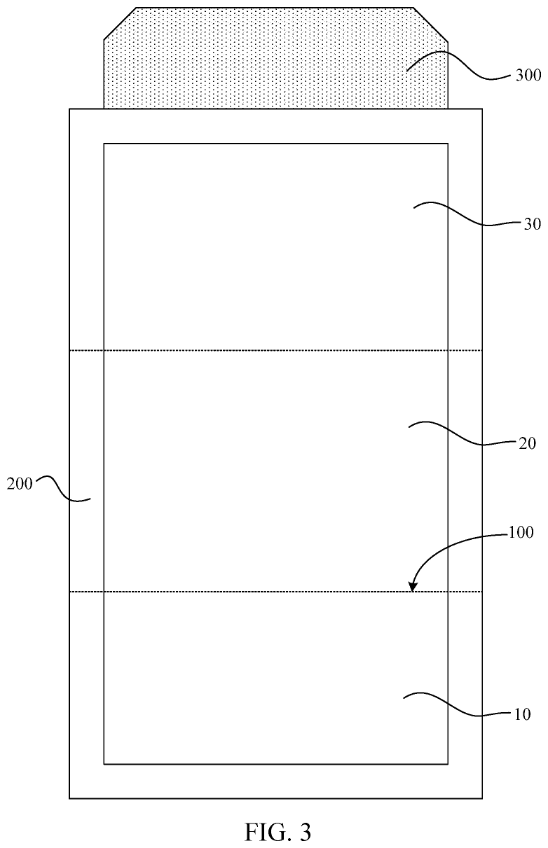

FIG. 3 is a schematic diagram of a foldable display panel. In an exemplary embodiment, as shown in FIG. 3, the foldable display panel includes a display region, a border region 200 at a periphery of the display region, and an integrated circuit 300 on one side (an upper side in the figure) of the display region. The display panel is folded to divide the display region into three display sub-regions. The three display sub-regions are a first display sub-region 10, a second display sub-region 20, and a third display sub-region 30 respectively. A folding line 100 is arranged between every two adjacent display sub-regions. The display panel shown in FIG. 3 may adopt the abovementioned driving circuit. The driving circuit may include a first shift register group, a second shift register group, and a third shift register group. A control module 50 includes a first GSTV signal output terminal GSTV1, a first ESTV signal output terminal ESTV1, a second GSTV signal output terminal GSTV2, a second ESTV signal output terminal ESTV2, a third GSTV signal output terminal GSTV3, and a third ESTV signal output terminal ESTV3. The first shift register group, the second shift register group, and the third shift register group respectively sequentially drive the first display sub-region 10, the second display sub-region 20, and the third display sub-region 30. That is, the first shift register group drives the first display sub-region 10, the second shift register group drives the second display sub-region 20, and the third shift register group drives the third display sub-region 30.

The control module 50 is in an integrated circuit 300. The shift register group may be arranged in the border region 200 corresponding to the display region. For example, the first shift register group may be in a border region on a left side or right side of the first display sub-region 10, the second shift register group may be in a border region on a left side or right side of the second display sub-region 20, and the third shift register group may be in a border region on a left side or right side of the third display sub-region 30.

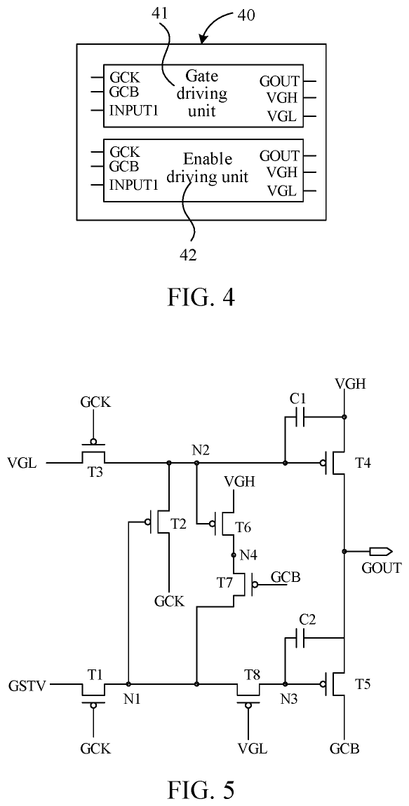

FIG. 4 is a schematic diagram of a shift register circuit. In an exemplary embodiment, as shown in FIG. 4, the shift register circuit 40 may include a gate driving unit 41. The gate driving unit 41 includes a first input terminal INPUT1, a gate output terminal GOUT, a first power terminal VGH, a second power terminal VGL, a first signal terminal GCK, and a second signal terminal GCB. The first input terminal INPUT1 may be a gate input terminal.

In an exemplary embodiment, as shown in FIG. 4, the shift register circuit 40 may further include an enable driving unit 42. The enable driving unit 42 includes a second input terminal INPUT2, an enable output terminal EOUT, a first power terminal VGH, a second power terminal VGL, a third signal terminal ECK, and a fourth signal terminal ECB. The second input terminal INPUT2 may be an enable input terminal.

FIG. 5 is a structural schematic diagram of a gate driving unit applicable to the shift register circuit in FIG. 2. The gate driving unit may include a first transistor to an eighth transistor (i.e., T1 to T8), a first memory capacitor C1, and a second memory capacitor C2. A control electrode of the first transistor T1 receives a first clock signal GCK. A first electrode of the first transistor T1 receives a first control signal GSTV. A second electrode of the first transistor T1 is connected with a first node N1. A control electrode of a second transistor T2 is connected with the first node N1. A first electrode of the second transistor T2 is connected with a second node N2. A second electrode of the second transistor T2 receives the first clock signal GCK. A control electrode of a third transistor T3 receives the first clock signal GCK. A first electrode of the third transistor T3 receives a second power signal VGL. A second electrode of the third transistor T3 is connected with the second node N2. A control electrode of a fourth transistor T4 is connected with the second node N2. A first electrode of the fourth transistor T4 receives a first power signal VGH. A second electrode of the fourth transistor T4 is connected with a gate output terminal GOUT of the gate driving unit. A control electrode of a fifth transistor T5 is connected with a third node N3. A first electrode of the fifth transistor T5 receives a second clock signal GCB. A second electrode of the fifth transistor T5 is connected with the gate output terminal GOUT of the gate driving unit. A control electrode of a sixth transistor T6 is connected with the second node N2. A first electrode of the sixth transistor T6 receives the first power signal VGH. A second electrode of the sixth transistor T6 is connected with a fourth node N4. A control electrode of a seventh transistor T7 receives the second clock signal GCB. A first electrode of the seventh transistor T7 is connected with the fourth node N4. A second electrode of the seventh transistor is connected with the first node N1. A control electrode of the eighth transistor T8 receives the second power signal VGL. A first electrode of the eighth transistor T8 is connected with the first node N1. A second electrode of the eighth transistor T8 is connected with the third node N3. A first electrode of the first memory capacitor C1 is connected with the first electrode of the fourth transistor T4. A second electrode of the first memory capacitor C1 is connected with the second node N2. A first electrode of the second memory capacitor C2 is connected with the third node N3. A second electrode of the second memory capacitor C2 is connected with the gate output GOUT of the gate driving unit.

Types of the first memory capacitor C1 and the second memory capacitor C2 may be selected according to a practical circuit. For example, they may be Metal Oxide Semiconductor (MOS) capacitors, metalized capacitors, or double-polysilicon capacitors. No special limits are made thereto in the present exemplary embodiment.

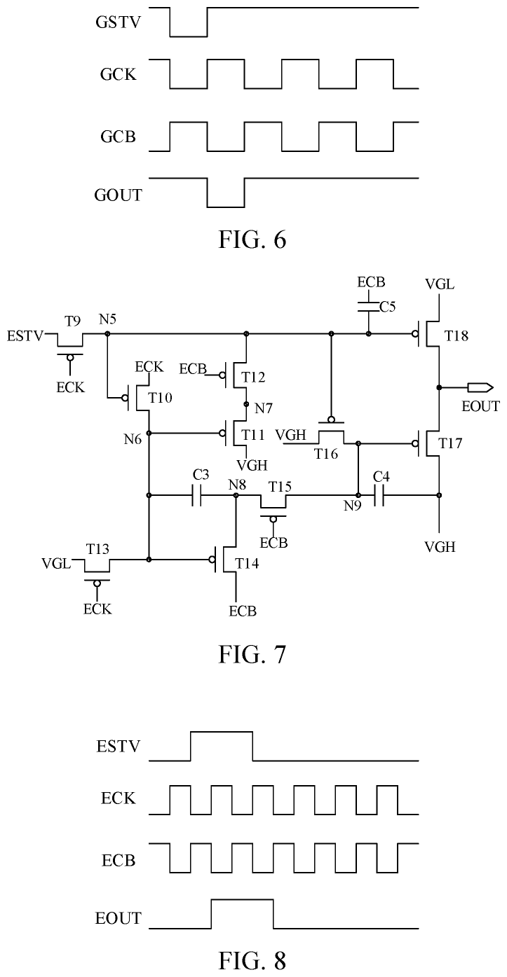

FIG. 6 is a working sequence diagram of the gate driving unit in FIG. 5. The working sequence diagram illustrates the first clock signal GCK, the second clock signal GCB, the first control signal GSTV, and a signal of the gate output terminal GOUT of the gate driving unit.

FIG. 6 is a working sequence diagram of the gate driving unit illustrated on such a basis that all the transistors in the gate driving unit are P-type thin film transistors.

In the abovementioned embodiment, all the transistors are P-type thin film transistors. However, it is easy for those skilled in the art to obtain a gate driving unit of which all transistors are N-type thin film transistors according to the shift register unit provided in the present disclosure. In an exemplary implementation mode of the present disclosure, all the transistors may be N-type thin film transistors. Since all the transistors are N-type thin film transistors, turn-on signals of the transistors are all high levels, and turn-off signals of the transistors are all low-level signals.

FIG. 7 is a structural schematic diagram of an enable driving unit applicable to the shift register circuit in FIG. 2. The enable driving unit may include a ninth transistor to an eighteenth transistor (i.e., T9 to T18), and a third memory capacitor to a fifth memory capacitor (C3 to C5). A control electrode of the ninth transistor T9 receives a third clock signal ECK. A first electrode of the ninth transistor T9 receives a second control signal ESTV. A second electrode of the ninth transistor T9 is connected with a fifth node N5. A control electrode of a tenth transistor T10 is connected with the fifth node N5. A first electrode of the tenth transistor T10 receives the third clock signal ECK. A second electrode of the tenth transistor T10 is connected with a sixth node N6. A control electrode of an eleventh transistor T11 is connected with the sixth node N6. A first electrode of the eleventh transistor T11 receives the first power signal VGH. A second electrode of the eleventh transistor T11 is connected with a seventh node N7. A control electrode of a twelfth transistor T12 receives a fourth clock signal ECB. A first electrode of the twelfth transistor T12 is connected with the fifth node N5. A second electrode of the twelfth transistor T12 is connected with the seventh node N7. A control electrode of a thirteenth transistor T13 receives the third clock signal ECK. A first electrode of the thirteenth transistor T13 receives the second power signal VGL. A second electrode of the third transistor T13 is connected with the sixth node N6. A control electrode of a fourteenth transistor T14 is connected with the sixth node N6. A first electrode of the fourteenth transistor T14 receives the fourth clock signal ECB. A second electrode of the fourteenth transistor T14 is connected with an eighth node N8. A control electrode of a fifteenth transistor T15 receives the fourth clock signal ECB. A first terminal of the fifteenth transistor T15 is connected with the eighth node N8. A second electrode of the fifteenth transistor T15 is connected with a ninth node N9. A control electrode of a sixteenth transistor T16 is connected with the fifth node N5. A first electrode of the sixteenth transistor T16 receives the first power signal VGH. A second electrode of the sixteenth transistor T16 is connected with the ninth node N9. A control electrode of a seventeenth transistor T17 is connected with the ninth node N9. A first electrode of the seventeenth transistor T17 receives the first power signal VGH. A second electrode of the seventeenth transistor T17 is connected with an enable output terminal EOUT of the enable driving unit. A control electrode of the eighteenth transistor T18 is connected with the fifth node N5. A first electrode of the eighteenth transistor T18 receives the second power signal VGL. A second electrode of the eighteenth transistor T18 is connected with the enable output terminal EOUT of the enable driving unit. A first electrode of the third memory capacitor C3 is connected with the sixth node N6. A second electrode of the third memory capacitor C3 is connected with the eighth node N8. A first electrode of a fourth memory capacitor C4 is connected with the ninth node N9. A second electrode of the fourth memory capacitor C4 receives the first power signal VGH. A first electrode of the fifth memory capacitor C5 receives the fourth signal ECB. A second electrode of the fifth memory capacitor C5 is connected with the fifth node N5.

Types of the third memory capacitor to the fifth memory capacitor (C3 to C5) may be selected according to a practical circuit. For example, they may be MOS capacitors, metalized capacitors, or double-polysilicon capacitors. No special limits are made thereto in the present exemplary embodiment.

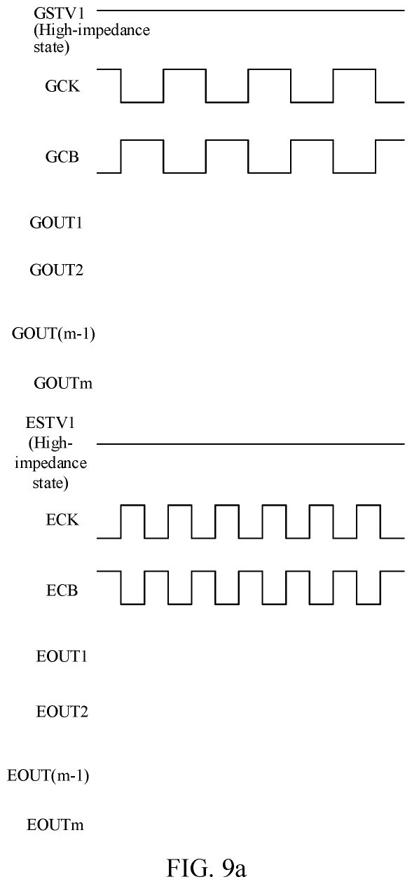

FIG. 8 is a working sequence diagram of the enable driving unit in FIG. 7. The working sequence diagram illustrates the third clock signal ECK, the fourth clock signal ECB, the second control signal ESTV, and a signal of the enable output terminal EOUT of the enable driving unit.

FIG. 8 is a working sequence diagram of the enable driving unit illustrated on such a basis that all the transistors in the enable driving unit are P-type thin film transistors.

In the abovementioned embodiment, all the transistors are P-type thin film transistors. However, it is easy for those skilled in the art to obtain an enable driving unit of which all transistors are N-type thin film transistors according to the enable driving unit provided in the present disclosure. In an exemplary implementation mode of the present disclosure, all the transistors may be N-type thin film transistors. Since all the transistors are N-type thin film transistors, turn-on signals of the transistors are all high levels, and turn-off signals of the transistors are all low-level signals.

It can be understood by those skilled in the art that the transistor adopted in all the embodiments of the present disclosure may be a thin-film transistor, or a field-effect transistor, or another device with the same characteristic. The thin film transistor may be an oxide semiconductor thin film transistor, a low temperature polysilicon thin film transistor, an amorphous silicon thin film transistor, or a microcrystalline silicon thin film transistor. The thin film transistor may select a bottom-gate thin film transistor or a top-gate thin film transistor as long as a switch function may be realized.

Schematic signal state diagrams of gate output terminals GOUT and enable output terminals EOUT of multiple shift register groups of the driving circuit of the embodiment of the present disclosure in different folding states of the display panel will be illustrated below taking the foldable display panel shown in FIG. 3 as an example. In the foldable display panel shown in FIG. 3, the first shift register group corresponding to the first display sub-region 10 includes m stages of shift register circuits 40, the second shift register group corresponding to the second display sub-region 20 includes n stages of shift register circuits 40, and the third shift register group corresponding to the third display sub-region 30 includes k stages of shift register circuits 40.

It can be understood by those skilled in the art that, for a foldable display panel, a display sub-region in a folded state does not display any image, namely the folded state is a non-display state, and a display sub-region in a non-folded state (i.e., an unfolded state) displays an image, namely the non-folded state is a display state, or the unfolded state is the display state.

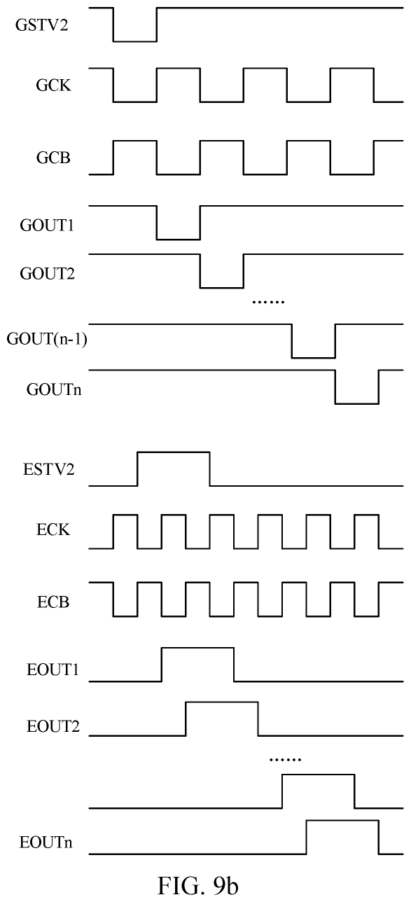

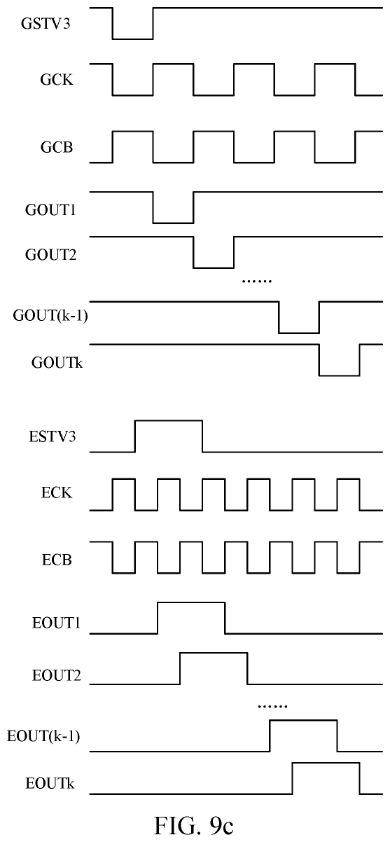

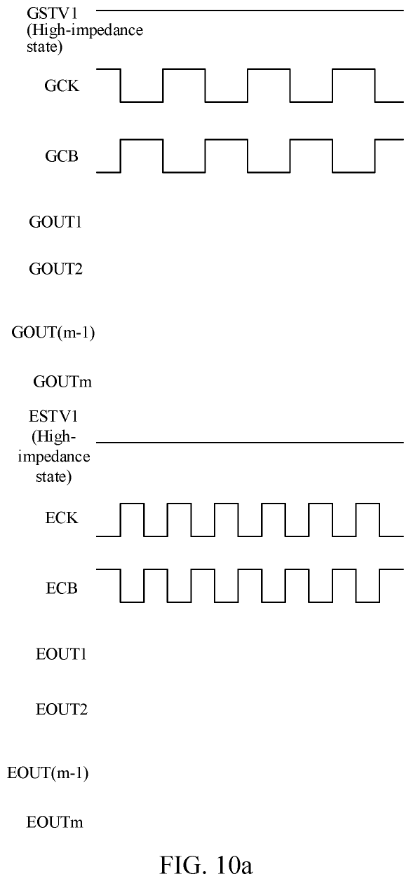

FIG. 9 is a schematic signal state diagram of a gate output terminal and enable output terminal of a display panel when a first display sub-region is in a folded state. FIG. 9a is a schematic signal state diagram of the first display sub-region. FIG. 9b is a schematic signal state diagram of the second display sub-region. FIG. 9c is a schematic signal state diagram of the third display sub-region.

As shown in FIG. 9, the first display sub-region is in a folded state, and the second display sub-region and the third display sub-region are in a non-folded state. In the first display sub-region, as shown in FIG. 9a, the control module inputs the first turn-off signal to the first GSTV signal output terminal GSTV1 and inputs the second turn-off signal to the first EST signal output terminal ESTV1 such that the first GSTV signal output terminal GSTV1 is in the high-impedance state and the first ESTV signal output terminal ESTV1 is in the high-impedance state. Therefore, all the gate output terminals GOUT and enable output terminals EOUT of the m stages of shift register circuits in the first display sub-region are turned off and may not output any gate driving signal and enable signal, and no image is displayed in the first display sub-region.

In the second display sub-region, as shown in FIG. 9b, the control module inputs the first turn-on signal to the second GSTV signal output terminal GSTV2 and inputs the second turn-on signal to the second ESTV signal output terminal ESTV2. Therefore, all the gate output terminals GOUT and enable output terminals EOUT of the n stages of shift register circuits in the second display sub-region are turned on and output corresponding gate driving signals and enable signals, and an image is displayed in the second display sub-region.

In the third display sub-region, as shown in FIG. 9c, the control module inputs the first turn-on signal to the third GSTV signal output terminal GSTV3 and inputs the second turn-on signal to the third ESTV signal output terminal ESTV3. Therefore, all the gate output terminals GOUT and enable output terminals EOUT of the k stages of shift register circuits in the third display sub-region are turned on and output corresponding gate driving signals and enable signals, and an image is displayed in the third display sub-region.

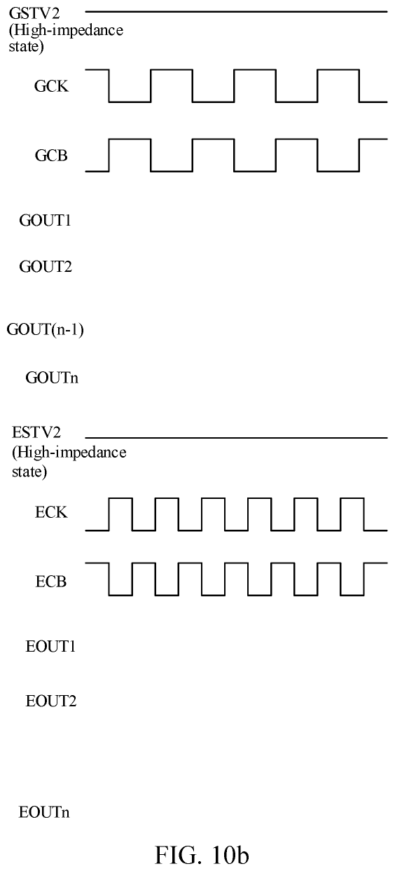

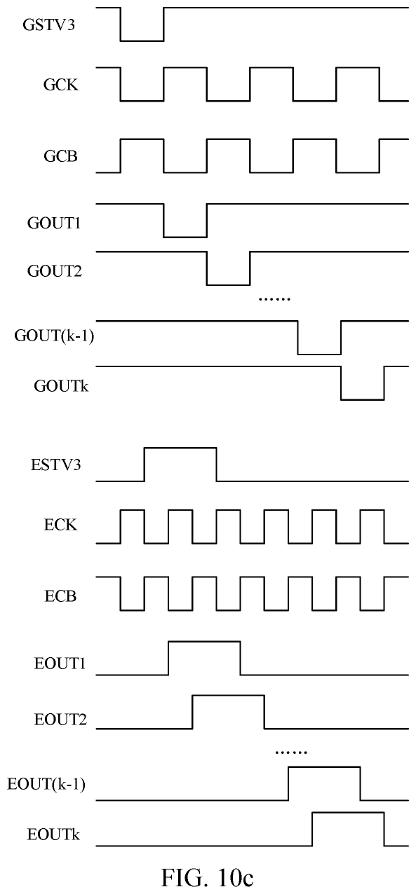

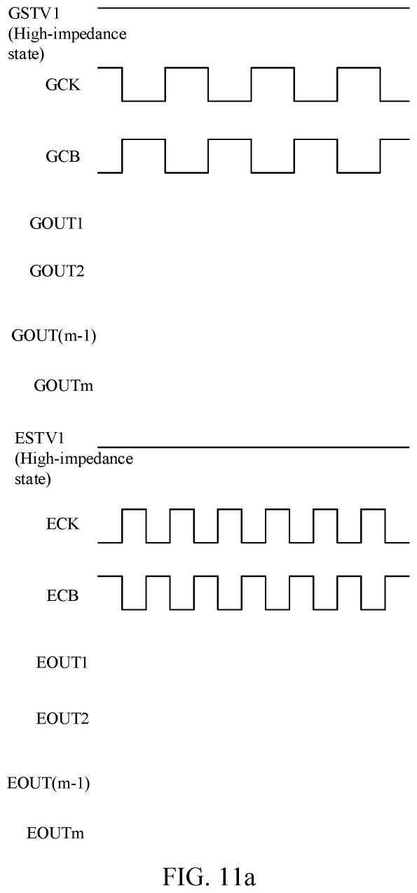

FIG. 10 is a schematic signal state diagram of a gate output terminal and enable output terminal of a display panel when both a first display sub-region and a second display sub-region are in a folded state. FIG. 10a is a schematic signal state diagram of the first display sub-region. FIG. 10b is a schematic signal state diagram of the second display sub-region. FIG. 10c is a schematic signal state diagram of the third display sub-region.

As shown in FIG. 10, the first display sub-region and the second display sub-region are in a folded state, and the third display sub-region is in a non-folded state. In the first display sub-region, as shown in FIG. 10a, the control module inputs the first turn-off signal to the first GSTV signal output terminal GSTV1 and inputs the second turn-off signal to the first EST signal output terminal ESTV1 such that the first GSTV signal output terminal GSTV1 is in the high-impedance state and the first ESTV signal output terminal ESTV1 is in the high-impedance state. Therefore, all the gate output terminals GOUT and enable output terminals EOUT of the m stages of shift register circuits in the first display sub-region are turned off and may not output any gate driving signal and enable signal, and no image is displayed in the first display sub-region.

In the second display sub-region, as shown in FIG. 10b, the control module inputs the first turn-off signal to the second GSTV signal output terminal GSTV2 and inputs the second turn-off signal to the second EST signal output terminal ESTV2 such that the second GSTV signal output terminal GSTV2 is in the high-impedance state and the second ESTV signal output terminal ESTV2 is in the high-impedance state. Therefore, all the gate output terminals GOUT and enable output terminals EOUT of the n stages of shift register circuits in the second display sub-region are turned off and may not output any gate driving signal and enable signal, and no image is displayed in the second display sub-region.

In the third display sub-region, as shown in FIG. 10c, the control module inputs the first turn-on signal to the third GSTV signal output terminal GSTV3 and inputs the second turn-on signal to the third ESTV signal output terminal ESTV3. Therefore, all the gate output terminals GOUT and enable output terminals EOUT of the k stages of shift register circuits in the third display sub-region are turned on and output corresponding gate driving signals and enable signals, and an image is displayed in the third display sub-region.

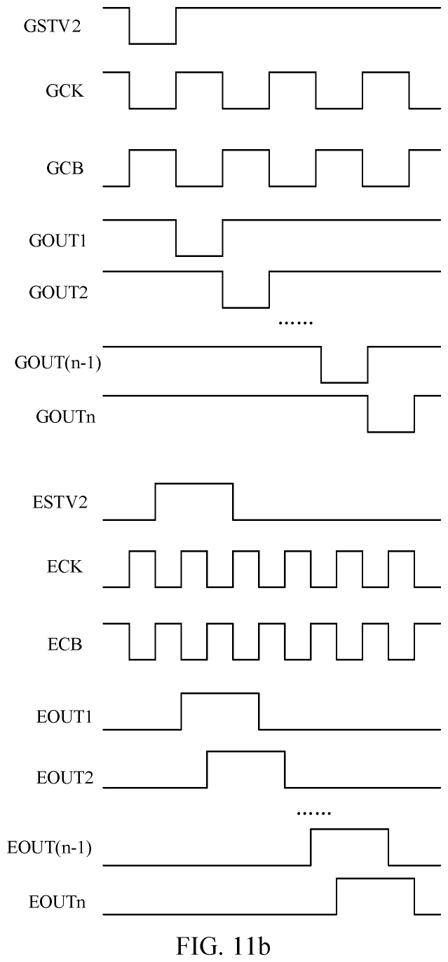

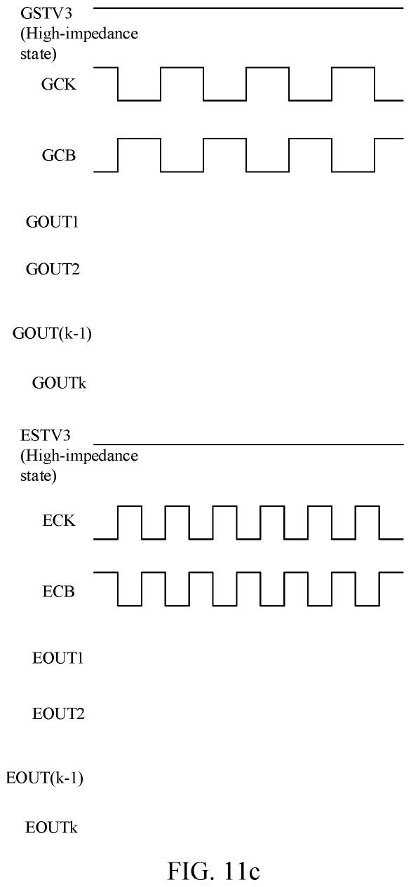

FIG. 11 is a schematic signal state diagram of a gate output terminal and enable output terminal of a display panel when a first display sub-region and a third display sub-region are in a folded state. FIG. 11a is a schematic signal state diagram of the first display sub-region. FIG. 11b is a schematic signal state diagram of the second display sub-region. FIG. 11c is a schematic signal state diagram of the third display sub-region.

As shown in FIG. 11, the first display sub-region and the third display sub-region are in a folded state, and the second display sub-region is in a non-folded state. In the first display sub-region, as shown in FIG. 11a, the control module inputs the first turn-off signal to the first GSTV signal output terminal GSTV1 and inputs the second turn-off signal to the first EST signal output terminal ESTV1 such that the first GSTV signal output terminal GSTV1 is in the high-impedance state and the first ESTV signal output terminal ESTV1 is in the high-impedance state. Therefore, all the gate output terminals GOUT and enable output terminals EOUT of the m stages of shift register circuits in the first display sub-region are turned off and may not output any gate driving signal and enable signal, and no image is displayed in the first display sub-region.

In the second display sub-region, as shown in FIG. 11b, the control module inputs the first turn-on signal to the second GSTV signal output terminal GSTV2 and inputs the second turn-on signal to the second ESTV signal output terminal ESTV2. Therefore, all the gate output terminals GOUT and enable output terminals EOUT of the n stages of shift register circuits in the second display sub-region are turned on and output corresponding gate driving signals and enable signals, and an image is displayed in the second display sub-region.

In the third display sub-region, as shown in FIG. 11c, the control module inputs the first turn-off signal to the third GSTV signal output terminal GSTV3 and inputs the second turn-off signal to the third EST signal output terminal ESTV3 such that the third GSTV signal output terminal GSTV3 is in the high-impedance state and the third ESTV signal output terminal ESTV3 is in the high-impedance state. Therefore, all the gate output terminals GOUT and enable output terminals EOUT of the k stages of shift register circuits in the third display sub-region are turned off and may not output any gate driving signal and enable signal, and no image is displayed in the third display sub-region.

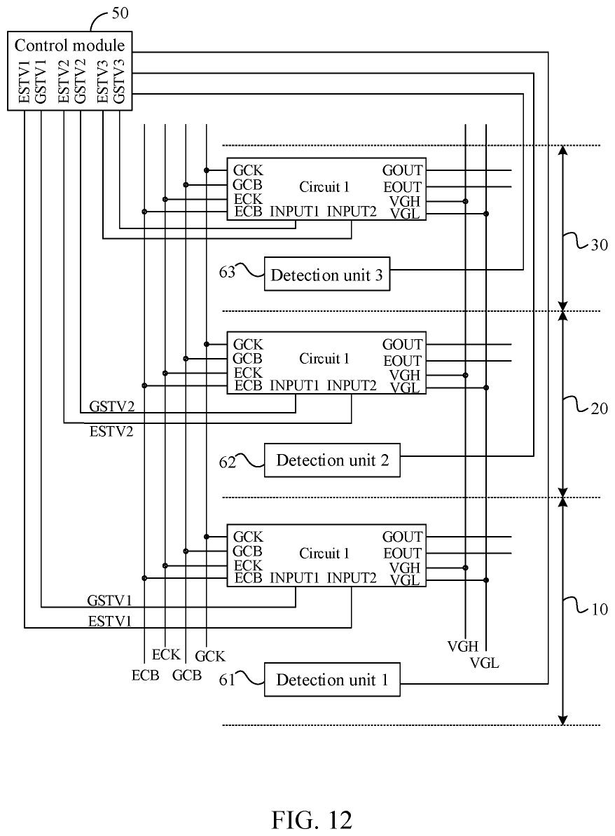

FIG. 12 is a schematic diagram of a driving circuit according to an exemplary embodiment. In an exemplary embodiment, as shown in FIG. 12, the driving circuit may further include a first detection unit 61 and second detection unit 62 that are connected with the control module. The control module 50 is arranged to output the first turn-on signal or the first turn-off signal to the first GSTV signal output terminal GSTV1 according to a detection signal of the first detection unit. The control module is arranged to output the first turn-on signal or the first turn-off signal to the second GSTV signal output terminal GSTV2 according to a detection signal of the second detection unit.

The control module 50 may further be arranged to output the second turn-on signal or the second turn-off signal to the first ESTV signal output terminal ESTV1 according to the detection signal of the first detection unit 61. The control module is arranged to output the second turn-on signal or the second turn-off signal to the second ESTV signal output terminal ESTV2 according to the detection signal of the second detection unit.

In an exemplary embodiment, as shown in FIG. 12, the driving circuit may further include a third detection unit 63 connected with the control module. The control module 50 is arranged to output the first turn-on signal or the first turn-off signal to the third GSTV signal output terminal GSTV3 according to a detection signal of the third detection unit. The control module 50 may further be arranged to output the second turn-on signal or the second turn-off signal to the third ESTV signal output terminal ESTV3 according to the detection signal of the third detection unit 63.

When the driving circuit is applied to the display panel shown in FIG. 3, the first detection unit 61, the second detection unit 62, and the third detection unit 63 may correspond to the first display sub-region 10, the second display sub-region 20, and the third display sub-region 30 one to one respectively. When a display sub-region is in a folded state, the corresponding detection unit generates a folding signal. When a display sub-region is in an unfolded state, the corresponding detection unit generates an unfolding signal.

When the control module receives a folding signal from the first detection unit 61, the control module outputs the first turn-off signal to the first GSTV signal output terminal GSTV1 and outputs the second turn-off signal to the first ESTV signal output terminal ESTV1, and no image is displayed in the first display sub-region. When the control module receives an unfolding signal from the first detection unit 61, the control module outputs the first turn-on signal to the first GSTV signal output terminal GSTV1 and outputs the second turn-on signal to the first ESTV signal output terminal ESTV1, and an image is displayed in the first display sub-region.

When the control module receives a folding signal from the second detection unit 62, the control module outputs the first turn-off signal to the second GSTV signal output terminal GSTV2 and outputs the second turn-off signal to the second ESTV signal output terminal ESTV2, and no image is displayed in the second display sub-region. When the control module receives an unfolding signal from the second detection unit 62, the control module outputs the first turn-on signal to the second GSTV signal output terminal GSTV2 and outputs the second turn-on signal to the second ESTV signal output terminal ESTV2, and an image is displayed in the second display sub-region.

When the control module receives a folding signal from the third detection unit 63, the control module outputs the first turn-off signal to the third GSTV signal output terminal GSTV3 and outputs the second turn-off signal to the third ESTV signal output terminal ESTV3, and no image is displayed in the third display sub-region. When the control module receives an unfolding signal from the third detection unit 62, the control module outputs the first turn-on signal to the third GSTV signal output terminal GSTV3 and outputs the third turn-on signal to the second ESTV signal output terminal ESTV3, and an image is displayed in the third display sub-region.

An embodiment of the present disclosure also provides a display panel. The display panel is a foldable display panel. As shown in FIG. 3, the display panel includes a display region, a border region 200 at a periphery of the display region, and an integrated circuit 300 on an upper side of the display region. The display panel is folded to divide the display region into three display sub-regions. The three display sub-regions are a first display sub-region 10, a second display sub-region 20, and a third display sub-region 30 respectively. The display panel adopts the abovementioned driving circuit.

The first display sub-region 10 may include multiple gate lines. Gate output terminals of multiple stages of shift register circuits of a first shift register group are connected with the multiple gate lines of the first display sub-region 10 in one-to-one correspondence.

The first display sub-region 10 may include multiple enable lines. Enable output terminals of the multiple stages of shift register circuits of the first shift register group are connected with the multiple enable lines of the first display sub-region 10 in one-to-one correspondence.

The second display sub-region 20 may include multiple gate lines. Gate output terminals of multiple stages of shift register circuits of a second shift register group are connected with the multiple gate lines of the second display sub-region 20 in one-to-one correspondence.

The second display sub-region 20 may include multiple enable lines. Enable output terminals of the multiple stages of shift register circuits of the second shift register group are connected with the multiple enable lines of the second display sub-region 20 in one-to-one correspondence.

The third display sub-region 30 may include multiple gate lines. Gate output terminals of multiple stages of shift register circuits of a third shift register group are connected with the multiple gate lines of the third display sub-region 30 in one-to-one correspondence.

The third display sub-region 30 may include multiple enable lines. Enable output terminals of the multiple stages of shift register circuits of the third shift register group are connected with the multiple enable lines of the third display sub-region 30 in one-to-one correspondence.

A first detection unit corresponds to the first display sub-region, and is arranged to detect a folding state of the first display sub-region.

A second detection unit corresponds to the second display sub-region, and is arranged to detect a folding state of the second display sub-region.

A third detection unit corresponds to the third display sub-region, and is arranged to detect a folding state of the third display sub-region.

The correspondences of the driving circuit and the foldable display panel when the foldable display panel includes two display sub-regions and three display sub-regions are introduced in the above embodiment. It can be understood by those skilled in the art that, when the foldable display panel is folded to form more display sub-regions, the driving circuit may be arranged to include shift register groups, detection units, GSTV signal output terminals, and ESTV signal output terminals in numbers corresponding to the number of the display sub-regions, thereby controlling each display sub-region respectively.

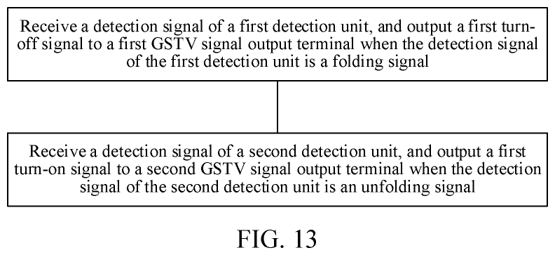

FIG. 13 is a schematic diagram of a driving method according to an exemplary embodiment of the present disclosure. An embodiment of the present disclosure also provides a driving method for a driving circuit. The driving circuit is the abovementioned driving circuit. The driving method may include the following operations.

A detection signal of a first detection unit is received, and a first turn-off signal to a first GSTV signal output terminal when the detection signal of the first detection unit is a folding signal.

A detection signal of a second detection unit is received, and a first turn-on signal is output to a second GSTV signal output terminal when the detection signal of the second detection unit is an unfolding signal.

In an exemplary embodiment, the driving method further includes the following operations.

A second turn-off signal is output to a first ESTV signal output terminal when the detection signal of the first detection unit is a folding signal.

A second turn-on signal is output to a second ESTV signal output terminal when the detection signal of the second detection unit is an unfolding signal.

The technical solution of the driving method of the present disclosure will be described below with the driving circuit shown in FIG. 12. In the foldable display panel corresponding to the driving circuit shown in FIG. 12, the first display sub-region of the foldable display panel is in a folded state, and both the second display sub-region and the third display sub-region are in an unfolded state. The driving method may include the following operations.

A detection signal of the first detection unit is received, and when the detection signal of the first detection unit is a folding signal, a first turn-off signal is output to the first GSTV signal output terminal, and a second turn-off signal is output to the first ESTV signal terminal. The step may include that: the control module 50 receives a detection signal of the first detection unit 61, and when the detection signal of the first detection unit 61 is a folding signal, the control module 50 outputs the first turn-off signal to the first GSTV signal output terminal GSTV1 to turn off the gate output terminal of the shift register circuit in the first shift register group to ensure no output at the gate output terminal; and the control module 50 outputs the second turn-off signal to the first ESTV signal output terminal ESTV1 to turn off the enable output terminal of the shift register circuit in the first shift register group to ensure no output at the enable output terminal, as shown in FIG. 9a.

A detection signal of the second detection unit is received, and when the detection signal of the second detection unit is a folding signal, a first turn-on signal is output to the second GSTV signal output terminal, and a second turn-on signal is output to the second ESTV signal terminal. The step may include that: the control module 50 receives a detection signal of the second detection unit 62, and when the detection signal of the second detection unit 62 is an unfolding signal, the control module 50 outputs the first turn-on signal to the second GSTV signal output terminal GSTV2 to turn on the gate output terminal of the shift register circuit in the second shift register group to enable the gate output terminal to output a gate driving signal; and the control module 50 outputs the second turn-on signal to the second ESTV signal output terminal ESTV2 to turn on the enable output terminal of the shift register circuit in the second shift register group to enable the enable output terminal to output an enable signal, as shown in FIG. 9b.

A detection signal of the third detection unit is received, and when the detection signal of the third detection unit is an unfolding signal, the first turn-on signal is output to the third GSTV signal output terminal, and the second turn-on signal is output to the third ESTV signal terminal. The step may include that: the control module 50 receives a detection signal of the third detection unit 63, and when the detection signal of the second detection unit 63 is an unfolding signal, the control module 50 outputs the first turn-on signal to the third GSTV signal output terminal GSTV3 to turn on the gate output terminal of the shift register circuit in the third shift register group to enable the gate output terminal to output a gate driving signal; and the control module 50 outputs the second turn-on signal to the third ESTV signal output terminal ESTV3 to turn on the enable output terminal of the shift register circuit in the third shift register group to enable the enable output terminal to output an enable signal, as shown in FIG. 9c.

It can be understood by those skilled in the art that the foldable display panel provided in the present disclosure may be any foldable product or component with a display function, such as a mobile phone, a tablet computer, a television, a display, a notebook computer, a digital photo frame, or a navigator.

Although the implementation modes of the present disclosure are disclosed above, the contents are only implementation modes adopted to easily understand the present disclosure and not intended to limit the present disclosure. Those skilled in the art may make any modifications and variations to implementation forms and details without departing from the spirit and scope disclosed by the present disclosure. However, the patent protection scope of the present disclosure should also be subject to the scope defined by the appended claims.

What is claimed is:

1. A driving circuit, comprising:
a first shift register group, comprising multiple stages of shift register circuits, wherein the shift register circuit of each stage comprises a first gate input terminal and a gate output terminal, and the first gate input terminals of the shift register circuits of the second stage to the last stage are connected with the gate output terminals of the shift register circuits of immediately previous stages;
a second shift register group, comprising multiple stages of shift register circuits, wherein the shift register circuit of each stage comprises a second gate input terminal and a gate output terminal, and the second gate input terminals of the shift register circuits of the second stage to the last stage are connected with the gate output terminals of the shift register circuits of immediately previous stages; and
a control module, comprising a first Gate Start Voltage (GSTV) signal output terminal and a second GSTV signal output terminal, wherein the first GSTV signal output terminal is connected with the first gate input terminal of the shift register circuit of the first stage in the first shift register group, the second GSTV signal output terminal is connected with the second gate input terminal of the shift register circuit of the first stage in the second shift register group, and the control module is arranged to output a first turn-on signal or a first turn-off signal to the first GSTV signal output terminal, and is further arranged to output the first turn-on signal or the first turn-off signal to the second GSTV signal output terminal.

2. The driving circuit according to claim 1, wherein the first turn-off signal comprises a high-impedance state.

3. The driving circuit according to claim 1, wherein
in the first shift register group, the shift register circuit of each stage further comprises a first enable input terminal and an enable output terminal, and the first enable input terminals of the shift register circuits of the second stage to the last stage are connected with the enable output terminals of the shift register circuits of immediately previous stages;
in the second shift register group, the shift register circuit of each stage further comprises a second enable input terminal and an enable output terminal, and the second enable input terminals of the shift register circuits of the second stage to the last stage are connected with the enable output terminals of the shift register circuits of immediately previous stages; and
the control module further comprises a first Emission Start Voltage (ESTV) signal output terminal and a second ESTV signal output terminal, the first ESTV signal output terminal is connected with the first enable input terminal of the shift register circuit of the first stage in the first shift register group, the second ESTV signal output terminal is connected with the second enable input terminal of the shift register circuit of the first stage in the second shift register group, and the control module is arranged to output a second turn-on signal or a second turn-off signal to the first ESTV signal output terminal, and is further arranged to output the second turn-on signal or the second turn-off signal to the second ESTV signal output terminal.

4. The driving circuit according to claim 3, wherein the second turn-off signal comprises a high-impedance state.

5. The driving circuit according to claim 3, wherein the shift register circuit further comprises a first signal terminal, a second signal terminal, a third signal terminal, and a fourth signal terminal, wherein the first signal terminal is connected with a first clock signal line, the second signal terminal is connected with a second clock signal line, the third signal terminal is connected with a third clock signal line, the fourth signal terminal is connected with a fourth clock signal line, the first clock signal and the second clock signal have a same period and opposite states, and the third clock signal and the fourth clock signal have a same period and opposite states.

6. The driving circuit according to claim 1, further comprising a first detection unit and a second detection unit that are connected with the control module, wherein the control module is arranged to output the first turn-on signal or the first turn-off signal to the first GSTV signal output terminal according to a detection signal of the first detection unit and output the first turn-on signal or the first turn-off signal to the second GSTV signal output terminal according to a detection signal of the second detection unit.

7. The driving circuit according to claim 3, further comprising a first detection unit and a second detection unit that are connected with the control module, wherein the control module is arranged to output the second turn-on signal or the second turn-off signal to the first ESTV signal output terminal according to a detection signal of the first detection unit and output the second turn-on signal or the second turn-off signal to the second ESTV signal output terminal according to a detection signal of the second detection unit.

8. The driving circuit according to claim 3, further comprising:
a third shift register group, comprising multiple stages of shift register circuits, wherein the shift register circuit of each stage comprises a third gate input terminal, a gate output terminal, a third enable input terminal, and an enable output terminal, the third gate input terminals of the shift register circuits of the second stage to the last stage are connected with the gate output terminals of the shift register circuits of immediately previous stages, and the third enable input terminals of the shift register circuits of the second stage to the last stage are connected with the enable output terminals of the shift register circuits of immediately previous stages; and
the control module further comprises a third GSTV signal output terminal and a third ESTV signal output terminal, the third GSTV signal output terminal is connected with the third gate input terminal of the shift register circuit of the first stage in the third shift register group, the third ESTV signal output terminal is connected with the third enable input terminal of the shift register circuit of the first stage in the third shift register group, and the control module is arranged to output the first turn-on signal or the first turn-off signal to the third GSTV signal output terminal to turn on or off the gate output terminal of the third shift register group, and is further arranged to output the second turn-on signal or the second turn-off signal to the third ESTV signal output terminal to turn on or off the enable output terminal of the third shift register group.

9. A display panel, the display panel being a foldable display panel and comprising a display region and a border region at a periphery of the display region, wherein the display region is folded to form a first display sub-region and a second display sub-region, the display panel comprises the driving circuit according to claim 1, each of the first display sub-region and the second display sub-region comprises multiple gate lines, the gate output terminals of the multiple stages of shift register circuits in the first shift register group are connected with the multiple gate lines of the first display sub-region in one-to-one correspondence, and the gate output terminals of the multiple stages of shift register circuits in the second shift register group are connected with the multiple gate lines of the second display sub-region in one-to-one correspondence.

10. The display panel according to claim 9, wherein the display panel is folded to further form a third display sub-region, wherein the third display sub-region comprises multiple gate lines, the driving circuit further comprises a third shift register group, and gate output terminals of multiple stages of shift register circuits in the third shift register group are connected with the multiple gate lines of the third display sub-region in one-to-one correspondence.

11. The display panel according to claim 9, wherein the driving circuit further comprises a first detection unit and a second detection unit, the first detection unit is arranged to detect a folding state of the first display sub-region, and the second detection unit is arranged to detect a folding state of the second display sub-region.

12. A driving method of a driving circuit, applied to the driving circuit according to claim 1, the driving method comprising:
receiving a detection signal of a first detection unit, and outputting the first turn-off signal to the first GSTV signal output terminal when the detection signal of the first detection unit is a folding signal; and
receiving a detection signal of a second detection unit, and outputting the first turn-on signal to the second GSTV signal output terminal when the detection signal of the second detection unit is an unfolding signal.

13. The driving method according to claim 12, further comprising:
outputting a second turn-off signal to a first Emission Start Voltage (ESTV) signal output terminal when the detection signal of the first detection unit is a folding signal; and
outputting a second turn-on signal to a second ESTV signal output terminal when the detection signal of the second detection unit is an unfolding signal.

14. The driving circuit according to claim 2, wherein
in the first shift register group, the shift register circuit of each stage further comprises a first enable input terminal and an enable output terminal, and the first enable input terminals of the shift register circuits of the second stage to the last stage are connected with the enable output terminals of the shift register circuits of immediately previous stages;
in the second shift register group, the shift register circuit of each stage further comprises a second enable input terminal and an enable output terminal, and the second enable input terminals of the shift register circuits of the second stage to the last stage are connected with the enable output terminals of the shift register circuits of immediately previous stages; and
the control module further comprises a first Emission Start Voltage (ESTV) signal output terminal and a second ESTV signal output terminal, the first ESTV signal output terminal is connected with the first enable input terminal of the shift register circuit of the first stage in the first shift register group, the second ESTV signal output terminal is connected with the second enable input terminal of the shift register circuit of the first stage in the second shift register group, and the control module is arranged to output a second turn-on signal or a second turn-off signal to the first ESTV signal output terminal, and is further arranged to output the second turn-on signal or the second turn-off signal to the second ESTV signal output terminal.

15. The driving circuit according to claim 14, wherein the second turn-off signal comprises a high-impedance state.

16. The driving circuit according to claim 14, wherein the shift register circuit further comprises a first signal terminal, a second signal terminal, a third signal terminal, and a fourth signal terminal, wherein the first signal terminal is connected with a first clock signal line, the second signal terminal is connected with a second clock signal line, the third signal terminal is connected with a third clock signal line, the fourth signal terminal is connected with a fourth clock signal line, the first clock signal and the second clock signal have a same period and opposite states, and the third clock signal and the fourth clock signal have a same period and opposite states.

17. The driving circuit according to claim 14, further comprising a first detection unit and a second detection unit that are connected with the control module, wherein the control module is arranged to output the second turn-on signal or the second turn-off signal to the first ESTV signal output terminal according to a detection signal of the first detection unit and output the second turn-on signal or the second turn-off signal to the second ESTV signal output terminal according to a detection signal of the second detection unit.

18. The driving circuit according to claim 14, further comprising:
a third shift register group, comprising multiple stages of shift register circuits, wherein the shift register circuit of each stage comprises a third gate input terminal, a gate output terminal, a third enable input terminal, and an enable output terminal, the third gate input terminals of the shift register circuits of the second stage to the last stage are connected with the gate output terminals of the shift register circuits of immediately previous stages, and the third enable input terminals of the shift register circuits of the second stage to the last stage are connected with the enable output terminals of the shift register circuits of immediately previous stages; and
the control module further comprises a third GSTV signal output terminal and a third ESTV signal output terminal, the third GSTV signal output terminal is connected with the third gate input terminal of the shift register circuit of the first stage in the third shift register group, the third ESTV signal output terminal is connected with the third enable input terminal of the shift register circuit of the first stage in the third shift register group, and the control module is arranged to output the first turn-on signal or the first turn-off signal to the third GSTV signal output terminal to turn on or off the gate output terminal of the third shift register group, and is further arranged to output the second turn-on signal or the second turn-off signal to the third ESTV signal output terminal to turn on or off the enable output terminal of the third shift register group.
